(19) United States
(12) Patent Application Publication
(10) Pub. No.: US 2012/0162933 A1
(43) Pub. Date: Jun. 28, 2012

(54) MOUNTING APPARATUS FOR EXPANSION CARD

(75) Inventors: XIAO-ZHU CHEN, Shenzhen City (CN); LEI LIU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/981,561

(22) Filed: Dec. 30, 2010

(30) Foreign Application Priority Data
Dec. 22, 2010 (CN) 201010600389.5

(51) Int. Cl. H05K 7/00

(52) U.S. Cl. 361/748

(57) ABSTRACT

A mounting apparatus for an expansion card includes a bracket, and a securing member. The bracket is capable of fixing a front end of the expansion card. The securing member is slidably mounted to the bracket back and forth, for fixing a rear end of the expansion card.

### BACKGROUND

1. Technical Field

The present disclosure relates to a mounting apparatus for expansion cards.

2. Description of Related Art

Typically, a securing member is immovably fixed in an electronic device, to secure a rear end of an expansion card, and prevent the expansion card from loosening. However, when there is a need to mount another expansion card having a different length, the securing member is not available.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an embodiment of a mounting apparatus together with an expansion card, the mounting apparatus includes a securing member.

FIG. 2 is an enlarged view of the securing member of FIG. 1, but viewed from another perspective.

FIG. 3 is an assembled, isometric view of FIG. 1, but viewed from another perspective.

FIG. 4 is an assembled, isometric view of the mounting apparatus of FIG. 1 together with another expansion card.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

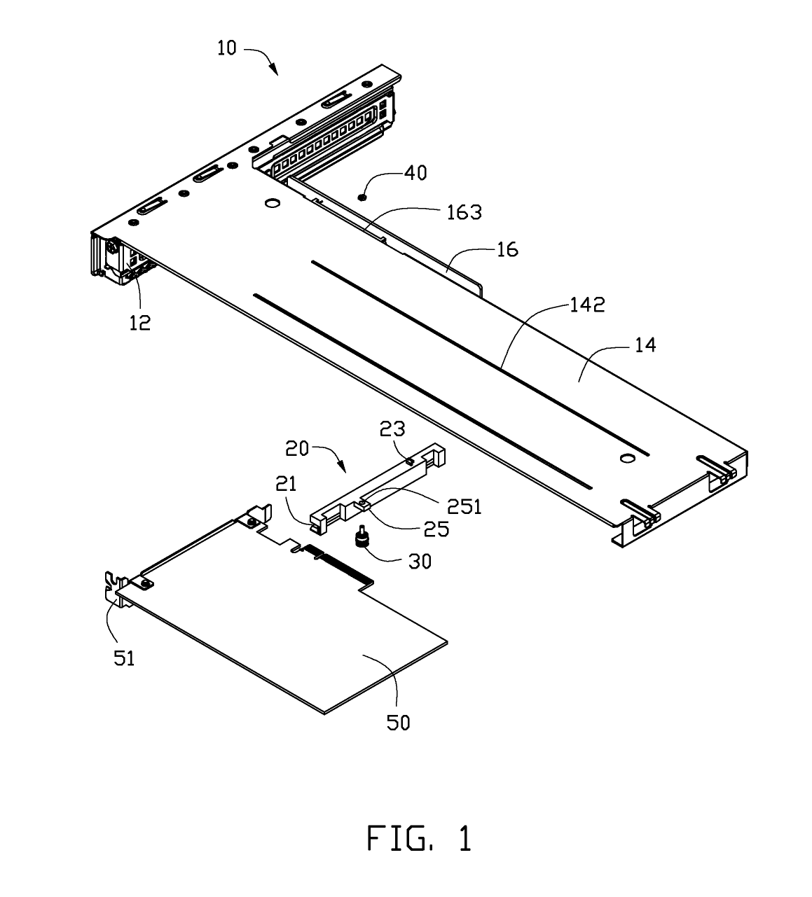

Referring to FIG. 1, an embodiment of a mounting apparatus includes a bracket 10, and an elongated securing member 20.

The bracket 10 includes an end wall 12, and a fixing plate 14 perpendicularly extending backwards from a top of the end wall 12. Two spaced slide slots 142 extending in a direction perpendicular to the end wall 12 are defined in the fixing plate 14. A circuit board 16 is mounted to a side of the fixing plate 14 perpendicular to the fixing plate 14 and the end wall 12. An expansion slot 163 is mounted to a side of the circuit board 16 towards the fixing plate 14.

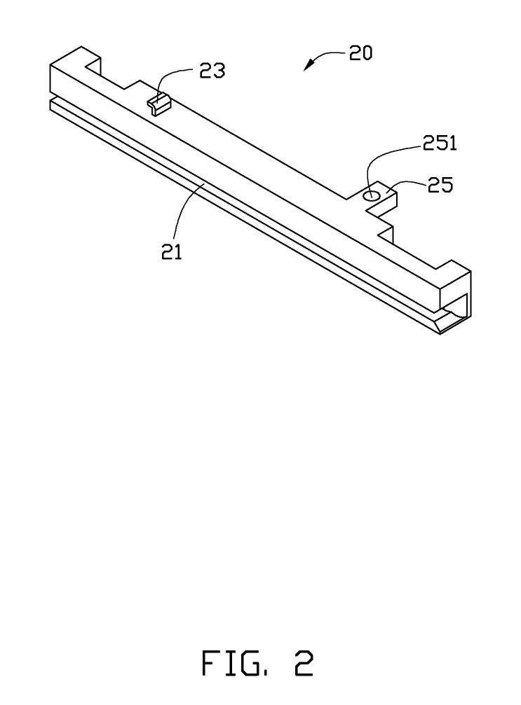

Referring to FIG. 2, a latching slot 21 is defined in a front side of the securing member 20, with two ends of the latching slot 21 extending through opposite ends of the securing member 20. A substantially L-shaped hook 23 extends upwards from a top of the securing member 20 adjacent to one of the ends of the securing member 20 and towards the end of the securing member 20. A tab 25 perpendicularly extends backwards from the top of the securing member 20 adjacent to the other end of the securing member 20. A through hole 251 is defined in the tab 25.

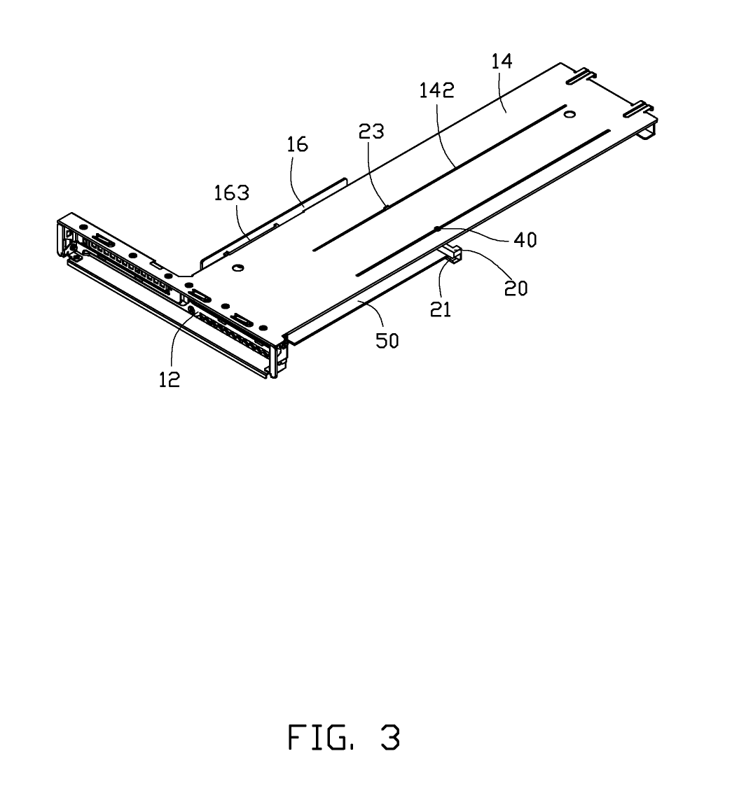

Referring to FIG. 3, in assembly, the securing member 20 is placed under the fixing plate 14 of the bracket 10. The hook 23 of the bracket 20 is extended through a corresponding slide slot 142 of the fixing plate 14, and engages with a top of the fixing plate 14. The through hole 251 of the tab 25 of the bracket 20 aligns with the other slide slot 142 of the fixing plate 14. A screw 30 is extended through the through hole 251 of the tab 25 and the other slide slot 142 of the fixing plate 14, and engages in a screw nut 40. Thereby, the securing member 20 is slidably connected to the fixing plate 14 of the bracket 10.

To mount a short expansion card 50 with a stop plate 51, the screw nut 40 is loosened, and the securing member 20 is slid away from the end wall 12 along the slide slots 142. The expansion card 50 is electrically connected to the expansion slot 163 of the circuit board 16, and the stop plate 51 of the expansion card 50 is fixed to the end wall 12 of the bracket 10. The securing member 20 is slid towards the end wall 12 along the slide slots 142, until a rear end of the expansion card 50 engages in the latching slot 21 of the securing member 20. The screw nut 40 is then fastened. Thereby, the expansion card 50 is firmly fixed to the mounting apparatus.

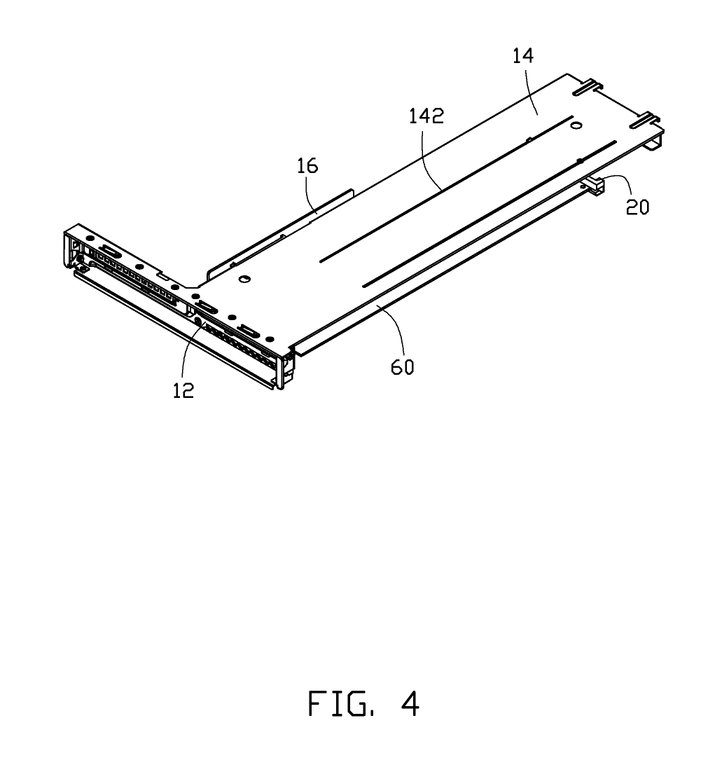

Referring to FIG. 4, the securing member 20 is slidable along the slide slots 142, and can fix expansion cards with different length, such as a long expansion card 60.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A mounting apparatus for an expansion card, the mounting apparatus comprising:
a bracket for fixing a front end of the expansion card; and
a securing member slidably mounted to the bracket, for fixing a rear end of the expansion card.

2. The mounting apparatus of claim 1, wherein the bracket comprises an end wall for fixing the front end of the expansion card, and a fixing plate perpendicularly extending backwards from a top of the end wall, the securing member is arranged under the fixing plate and slidably connected to the fixing plate.

3. The mounting apparatus of claim 2, wherein a latching slot is defined in a front side of the securing member, for engaging with the rear end of the expansion card.

4. The mounting apparatus of claim 3, wherein two ends of the latching slot respectively extend through opposite ends of the securing member.

5. The mounting apparatus of claim 3, wherein two spaced slide slots extending in a direction perpendicular to the end wall are defined in the fixing plate, a substantially L-shaped hook extends upwards from a top of the securing member adjacent to an end of the securing member and towards the end of the securing member, a tab extends backwards from the top of the securing member adjacent to an opposite end of the securing member, a through hole is defined in the tab, the hook is extended through one of the slide slots of the fixing plate and engages with a top of the fixing plate, a screw is extended through the through hole of the tab and the other slide slot of the fixing plate, and engages in a screw nut.

6. The mounting apparatus of claim 2, wherein a circuit board is mounted to a side of the fixing plate perpendicular to the fixing plate and the end wall, an expansion slot is mounted to a side of the circuit board towards the fixing plate to be electrically connected to the expansion card.
